(19) United States
(12) Patent Application Publication
(10) Pub. No.: US 2020/0161125 A1
(43) Pub. Date: May 21, 2020

(54) CLEANING APPARATUS AND METHOD FOR CHIP-STACKED STRUCTURE

(71) Applicant: GRAND PROCESS TECHNOLOGY CORPORATION, Hsinchu City (TW)

(72) Inventors: Fu-Yuan HUANG, Hsinchu City (TW); Zong-En WU, Hsinchu City (TW); Chih-Cheng WANG, Hsinchu City (TW)

(21) Appl. No.: 16/292,446

(22) Filed: Mar. 5, 2019

(30) Foreign Application Priority Data
Nov. 19, 2018 (TW) 107141172

(51) Int. Cl. H01L 21/02; B08B 3/08; B08B 7/00; B08B 5/02; B08B 7/04; H01L 21/67; H01L 23/00; H01L 25/065; H01L 25/00

(52) U.S. Cl. CPC H01L 21/02057; H01L 2225/06513; B08B 7/0071; B08B 5/02; B08B 7/04; H01L 21/67051; H01L 21/67109; H01L 24/16; H01L 24/81; H01L 25/0652; H01L 25/50; H01L 2224/16145; H01L 2224/81011; H01L 2224/81911; B08B 3/08

(57) ABSTRACT

A cleaning apparatus and a method for removing residue from a chip-stacked structure are provided. The cleaning apparatus includes: a platform for placing thereon the chip-stacked structure and a two-fluid nozzle movable relative to the platform to reach a position in alignment with an interval between two adjacent chips, where the two-fluid nozzle is configured to apply a gas-liquid mixture including a chemical liquid and a gas to the chip-stacked structure. The chemical liquid of the gas-liquid mixture separates the residue in a gap from a its attached surface, and an impact force exerted by the gas of the gas-liquid mixture causes the residue to be carried out of the gap.

### FIELD OF DISCLOSURE

The present disclosure relates to a cleaning apparatus and method, and more particularly to a cleaning apparatus and method for removing residues from a chip-stacked structure.

### BACKGROUND

A general three-dimensional integrated circuit packaging process includes four major steps: via formation, via filling, wafer thinning, and wafer bonding. A cleaning step must be performed before and after each of the four processing steps to avoid contamination of the wafer during processing thereof. Furthermore, the step of wafer bonding can be roughly divided into three types: chip to wafer (C2W), chip to chip (C2C), and wafer to wafer (W2W). However, a gap either formed between the wafers or formed between the wafer and the chip is usually 20 to 50 μm. Therefore, how to effectively remove the residues in such a tiny gap is a technical bottleneck and challenge that urgently need to be overcome.

Taiwan Patent Publication No. TW 1539515 has disclosed a cleaning method of chip-stacked structure and cleaning apparatus that can remove a flux or other impurities in a tiny gap between a wafer and a chip. In this patent publication, a roller-type or a brush-type sliding structure is provided at a bottom of a liquid suction device, so that the liquid suction device can slide on the substrate by the sliding structure to move to a cleaning position. The liquid suction device exerts a downward pressure on the chip-stacked structure, which easily causes damage or breakage to chip of the chip-stacked structure.

Accordingly, it is necessary to provide a cleaning apparatus and method to solve the technical problem in the prior art.

### SUMMARY OF DISCLOSURE

In order to solve technical problems mentioned above, an object of the present disclosure is to provide a cleaning apparatus and method in which the cleaning apparatus cleans the chip-stacked structure in a non-contact manner, thereby avoiding the problem of chip damage caused by applying a downward pressure to the chip-stacked structure.

In order to achieve the objects described above, the present disclosure provides a cleaning apparatus for removing residue from a chip-stacked structure, the chip-stacked structure including a substrate and a plurality of chips, a gap being defined between the chips being separated and the substrate, and the residue being located in the gap, the cleaning apparatus including:

a platform configured to place the chip-stacked structure thereon;

a liquid supply device configured to provide a chemical liquid;

a gas supply device configured to provide a gas; and

a two-fluid nozzle movable relative to the platform to reach a position in alignment with an interval between two adjacent chips,

where the two-fluid nozzle is connected to the liquid supply device and the gas supply device and configured to apply a gas-liquid mixture including the chemical liquid and the gas to the substrate of the chip-stacked structure, such that the gas-liquid mixture flows into the gap along a first side of the gap; and

where the residue in the gap is separated from its attached surface by the chemical liquid of the gas-liquid mixture, and an impact force exerted by the gas of the gas-liquid mixture causes the residue to be carried out of the gap through a second side of the gap.

In one preferable embodiment of the present disclosure, the cleaning apparatus further includes a precise driving device configured to control the two-fluid nozzle to move along a vertical direction and a horizontal direction with respect to the platform.

In one preferable embodiment of the present disclosure, the precise driving device includes a vertical lifting mechanism configured to control the two-fluid nozzle to move along the vertical direction with respect to the platform, and the vertical lifting mechanism includes a stepper motor.

In one preferable embodiment of the present disclosure, the precise driving device includes a horizontal moving mechanism configured to control the two-fluid nozzle to move along the horizontal direction with respect to the platform, and the horizontal moving mechanism includes an X-Y table.

In one preferable embodiment of the present disclosure, the cleaning apparatus further includes a chamber, where the platform and the two-fluid nozzle are disposed in the chamber, and an extraction opening is provided at a bottom of the chamber.

In one preferable embodiment of the present disclosure, the cleaning apparatus further includes a gas-liquid separation device, where the gas-liquid separation device is connected to the extraction opening of the chamber for gas-liquid separation of the gas-liquid mixture which is extracted through the extraction opening.

In one preferable embodiment of the present disclosure, the gas supply device includes a heater configured to heat the gas in the gas supply device to a temperature substantially the same as a temperature of the chemical liquid.

In one preferable embodiment of the present disclosure, the gas supply device includes a humidifier configured to increase humidity of the gas in the gas supply device.

In one preferable embodiment of the present disclosure, the platform includes another heater configured to heat the chip-stacked structure on the platform to maintain it at a processing temperature.

In one preferable embodiment of the present disclosure, the cleaning apparatus includes a plurality of two-fluid nozzles arranged in a row in a side-by-side manner, and the plurality of two-fluid nozzles are movable relative to the platform to reach a position in alignment with an interval between two adjacent rows of chips.

In one preferable embodiment of the present disclosure, a front end of the two-fluid nozzle of the cleaning apparatus is formed at an angle with respect to a surface of the chip-stacked structure to be cleaned.

In one preferable embodiment of the present disclosure, the two-fluid nozzle includes a high-pressure cleaning nozzle.

The present disclosure also provides a cleaning method, performed by a cleaning apparatus which includes a platform, a liquid supply device, a gas supply device, a two-fluid nozzle, and a precise driving device, and the cleaning method used for removing residue from a chip-stacked structure, and the chip-stacked structure including a substrate and a plurality of chips, a gap being defined between the chips and the substrate, and the residue being located in the gap, the cleaning method including:

placing the chip-stacked structure on the platform;

controlling the precise driving device to move the two-fluid nozzle to reach a position in alignment with an interval between two adjacent chips;

providing a chemical liquid to the two-fluid nozzle by the liquid supply device, and providing a gas to the two-fluid nozzle by the gas supply device;

applying a gas-liquid mixture including the chemical liquid and the gas to the substrate of the chip-stacked structure, such that the gas-liquid mixture flows into the gap along a first side of the gap, where the residue in the gap is separated from its attached surface by the chemical liquid of the gas-liquid mixture, and an impact force exerted by the gas of the gas-liquid mixture causes the residue to be carried out of the gap through a second side of the gap.

In one preferable embodiment of the present disclosure, after the chip-stacked structure is placed on the platform, the cleaning method further includes: controlling a horizontal movement of the two-fluid nozzle over the platform by a horizontal moving mechanism of the precise driving device, and controlling the two-fluid nozzle to move along a vertical direction with respect to the platform by a vertical lifting mechanism of the precise driving device to align the two-fluid nozzle with the first side of the gap.

In one preferable embodiment of the present disclosure, the horizontal moving mechanism includes an X-Y table.

In one preferable embodiment of the present disclosure, the cleaning apparatus further includes a chamber and a gas-liquid separation device, where an extraction opening is provided at a bottom of the chamber, and the gas-liquid separation device is connected with the extraction opening of the chamber, and the cleaning method also includes: performing gas-liquid separation of the gas-liquid mixture which is extracted through the extraction opening by the gas-liquid separation device.

In one preferable embodiment of the present disclosure, the gas supply device of the cleaning apparatus further includes a heater, and before the gas supply device provides a gas to the two-fluid nozzle, the cleaning method further includes: heating the gas in the gas supply device to a temperature substantially the same as a temperature of the chemical liquid by the heater.

In one preferable embodiment of the present disclosure, the gas supply device of the cleaning apparatus further includes a humidifier, and before the gas supply device provides a gas to the two-fluid nozzle, the cleaning method further includes: increasing humidity of the gas in the gas supply device by the humidifier.

In one preferable embodiment of the present disclosure, the platform of the cleaning apparatus further includes another heater, and the cleaning method further includes: heating the chip-stacked structure on the platform by the heater to maintain it at a processing temperature.

In one preferable embodiment of the present disclosure, after the residue in the gap is removed by the gas-liquid mixture, the cleaning method further includes:

providing a cleaning liquid to the two-fluid nozzle by the liquid supply device; and

spraying the cleaning liquid on the chip-stacked structure by the two-fluid nozzle to remove the gas-liquid mixture on the chip-stacked structure.

In one preferable embodiment of the present disclosure, after the residue in the gap is removed by the gas-liquid mixture, the cleaning method further includes: spraying a cleaning liquid on a back side of the substrate to remove the gas-liquid mixture on the back side of the substrate.

In one preferable embodiment of the present disclosure, after the residue in the gap is removed by the gas-liquid mixture, the cleaning method further includes: spraying a volatile solvent and a drying gas on the chip-stacked structure to remove moisture from a surface of the chip-stacked structure.

In one preferable embodiment of the present disclosure, after the residue in the gap is removed by the gas-liquid mixture, the cleaning method further includes: placing the chip-stacked structure in an oven to remove moisture from a surface of the chip-stacked structure.

In comparison to prior art, the present disclosure uses a two-fluid nozzle to apply a gas-liquid mixture to a chip-stacked structure in a cleaning apparatus, and cleans a residue on the chip-stacked structure by the gas-liquid mixture. Upon cleaning, a chemical liquid of the gas-liquid mixture separates the residue in the gap from its attached surface, and an impact force exerted by a gas of the gas-liquid mixture causes the residue to be carried out of the gap through a second side of the gap. By this design, the present disclosure can achieve a non-contact cleaning of the chip-stacked structure, thereby avoiding the problem of chip damage caused by applying a downward pressure on the chip-stacked structure.

### BRIEF DESCRIPTION OF DRAWINGS

FIG. 1 shows a schematic diagram of a cleaning apparatus according to a first preferred embodiment of the present disclosure.

FIG. 2 is an enlarged view showing a part of the cleaning apparatus of FIG. 1.

FIG. 3 shows a schematic diagram of a moving mechanism of the cleaning apparatus.

FIG. 4 shows a schematic diagram of a drying apparatus used in a cleaning method of the present disclosure.

FIG. 5 is an enlarged view showing a part of a cleaning apparatus according to a second preferred embodiment of the present disclosure.

FIG. 6 is an enlarged view showing a part of a cleaning apparatus according to a third preferred embodiment of the present disclosure.

### DETAILED DESCRIPTION

The structure and the technical means adopted by the present disclosure to achieve the above and other objects can be best understood by referring to the following detailed description of the preferred embodiments and the accompanying drawings.

A chip of a microprocessor includes a logic unit and a plurality of cache memories. If both the logic unit and the cache memories are configured in a two-dimensional (2-D) arrangement, a physical size of the chip will limit the number of the cache memories (due to poor processing of the large chips), thereby limiting performance of the microprocessor. In order to solve the problem of the 2-D arrangement of the chip, a three-dimensional (3D) integrated circuit is being actively developed. In general, a typical 3D-IC packaging process includes four steps: via formation, via filling, wafer thinning, and wafer bonding. A cleaning step must be performed before and after each of the four processing steps to avoid contamination of the wafer during processing thereof. Furthermore, the step of wafer bonding can be roughly divided into three types: chip to wafer (C2W), chip to chip (C2C), and wafer to wafer (W2W). However, a gap either formed between the wafers or formed between the wafer and the chip is usually 20 to 50 μm. The cleaning apparatus and cleaning method of the present disclosure can achieve the removal the residues in such a tiny gap.

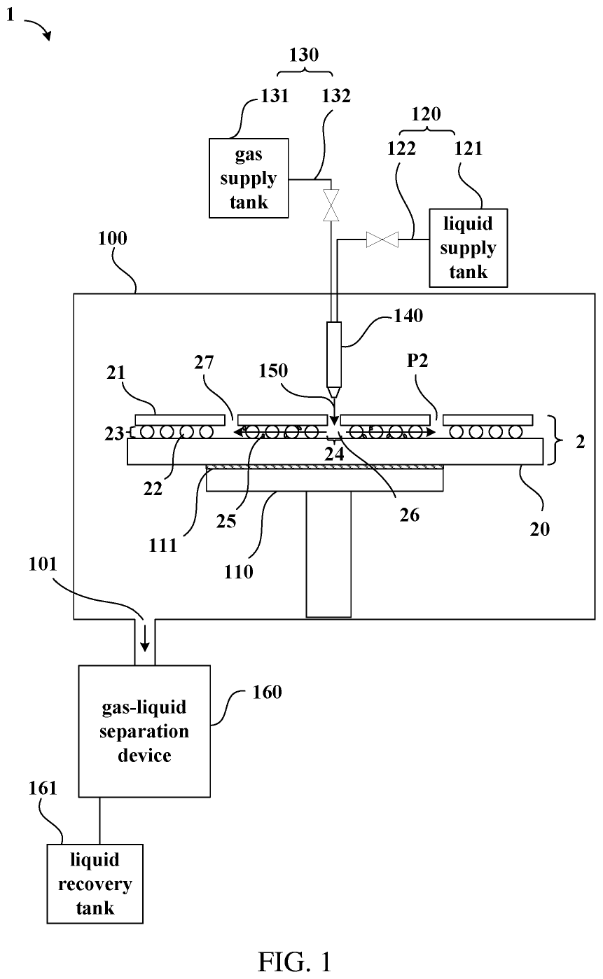

Referring to FIG. 1, which shows a schematic diagram of a cleaning apparatus 1 according to a first preferred embodiment of the present disclosure. The cleaning apparatus 1 is used for removing residues 25 in the chip-stacked structure 2, where the residue 25 may be a substance remaining from a previous process, such as flux, resin, adhesive, particles, organic matter, inorganic matter, and the like. The chip-stacked structure 2 is a three-dimensional integrated circuit board that includes a substrate 20 and a plurality of chips 21 arranged in an array. A plurality of connection members 22 are provided between the chips 21 and the substrate 20. The connection member 22 can be a solder ball or any suitable element that bonds the substrate 20 and chips 21 together. The connection member 22 is used to connect the substrate 20 and the chips 21 such that a gap 23 is defined between the substrate 20 and the chips 21. The substance to be removed by the cleaning apparatus 1 is the residues 25 that are located in the gap 23 between the substrate 20 and the chips 21.

As shown in FIG. 1, the cleaning apparatus 1 includes a chamber 100, a platform 110, a liquid supply device 120, a gas supply device 130, a two-fluid nozzle 140, and a gas-liquid separation device 160, where the platform 110 and the two-fluid nozzle 140 are located in the chamber 100. An extraction opening 101 is provided at a bottom of the chamber 100, and the gas-liquid separation device 160 is connected to the extraction opening 101 of the chamber 100. The platform 110 is used to place thereon the chip-stacked structure 2. The platform 110 includes a heater 111 for heating the chip-stacked structure 2 on the platform 110 to maintain it at an appropriate processing temperature, i.e., a specific temperature for achieving the processing of the chip-stacked structure 2.

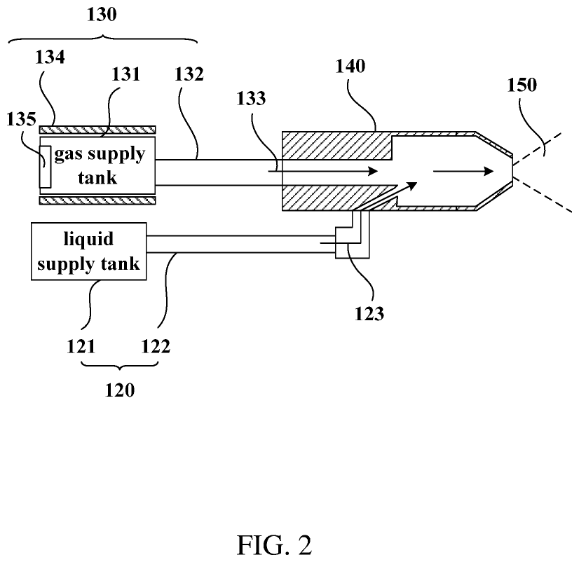

Referring to FIG. 1 and FIG. 2, where FIG. 2 is an enlarged view showing a part of the cleaning apparatus 1 of FIG. 1. The liquid supply device 120 includes a liquid supply tank 121 and a pipe 122, wherein the liquid supply tank 121 contains a chemical liquid 123 therein. The gas supply device 130 includes a gas supply tank 131 and a pipe 132 in which the gas supply tank 131 contains gas 133. Alternatively, the gas 133 may be nitrogen, clean dry air (CDA), or the like. The two-fluid nozzle 140 is connected to the liquid supply device 120 and the gas supply device 130 for mixing the chemical liquid 123 supplied from the liquid supply device 120 and the gas 133 supplied from the gas supply device 130 to form a gas-liquid mixture 150, and the gas-liquid mixture 150 is sprayed onto the substrate 20 of the chip-stacked structure 2.

As shown in FIG. 2, the gas supply device 130 further includes a heater 134 and a humidifier 135. In order to remove the residue 25 on the chip-stacked structure 2, the chemical liquid 123 with a certain temperature accelerates the reaction between the chemical liquid 123 and the residue 25, so that the residue 25 is separated from the its attached surface. However, when the gas 133 is mixed with the chemical liquid 123, the gas 133 will lower the temperature of the chemical liquid 123. Accordingly, the present disclosure provides the heater 134 such that the gas 133 in the gas supply device 130 can be heated to a temperature close to that of the chemical liquid 123, thereby avoiding the problem that the chemical liquid 123 has a temperature drop due to the gas 133 with low temperature. Furthermore, the present disclosure increases humidity of the gas 133 in the gas supply device 130 by providing the humidifier 135 to prevent the temperature of the chemical liquid 123 from being affected by humidity of the gas 133.

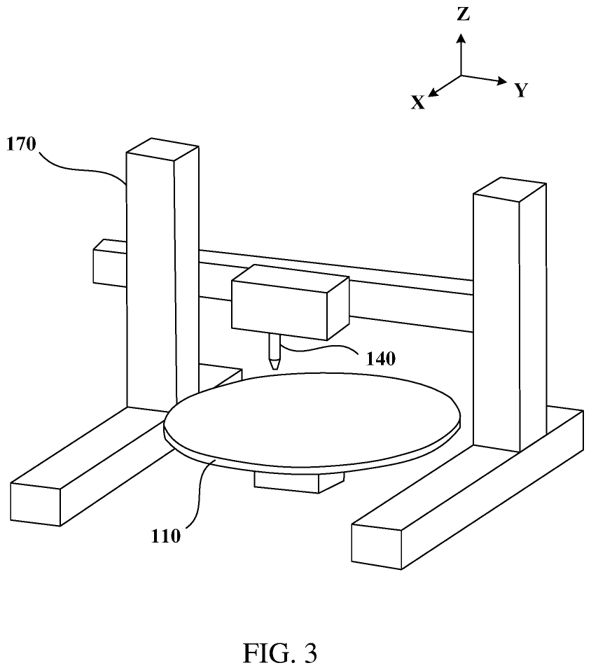

Referring to FIG. 3, which shows a schematic diagram of a moving mechanism of the cleaning apparatus 1. The moving mechanism of the cleaning apparatus 1 can be implemented by a precise driving device 170. The precise driving device 170 has a vertical lifting mechanism and a horizontal moving mechanism. The vertical lifting mechanism and the horizontal moving mechanism of the vertical lifting device 170 are respectively electrically connected to a main control device (for example, a computer), and actions of the movement mechanism of the cleaning apparatus 1 can be set by a control program in the main control device.

As shown in FIG. 3, the precise driving device 170 is connected to the two-fluid nozzle 140. The vertical lifting mechanism has a connection member and a precise driving element (e.g., a stepper motor) which are connected to the two-fluid nozzle 140 for controlling the two-fluid nozzle 140 to move along a vertical direction relative to the platform 110 (i.e., a direction away from or toward the platform 110). By providing the precise driving element, the two-fluid nozzle 140 can be precisely controlled to move up and down. Preferably, the precision driving device 170 can be used with a coordinate measuring mechanism to record a moving position and speed of the two-fluid nozzle 140 in the vertical direction. In addition, the horizontal moving mechanism is used for controlling horizontal movement of the two-fluid nozzle 140. For example, the horizontal moving mechanism can employ an X-Y table to precisely control the horizontal movement of the two-fluid nozzle 140 so that the two-fluid nozzle can accurately align with a cleaning position. Furthermore, the X-Y table can be used with a point recording device for recording the movement position of the two-fluid nozzle 140, so as to facilitate a rapid search and reach of the two-fluid nozzle 140 for a positioning point required by a new chip-stacked structure 2 having the same pattern as the previous one. It should be noted that in order to cooperate with the above precise point setting, the platform 110 preferably holds the chip-stacked structure 2 thereon by vacuum suction, thus ensuring that the chip-stacked structure 2 does not move relative to the platform 110 during the cleaning process.

It is an object of the present disclosure to provide a cleaning apparatus and method in which the cleaning apparatus 1 cleans the chip-stacked structure 2 in a non-contact manner, thereby avoiding the problem of damage of chip 21 of the chip-stacked structure 2 caused by applying a downward pressure on the chip-stacked structure 2. Part of the steps of the cleaning method of the present disclosure is performed by the cleaning apparatus 1, where the specific steps of the cleaning method are described in detail later with the cleaning apparatus 1 described above.

The cleaning method of the present disclosure includes the following steps. First, referring to FIG. 1, the chip-stacked structure 2 is placed on the platform 110. The heater 111 on the platform 110 is turned on, and the chip-stacked structure 2 on the platform 110 is heated to maintain the chip-stacked structure 2 at the appropriate processing temperature. By maintaining the temperature, the subsequently applied chemical liquid 123 can be maintained at an appropriate processing temperature without being cooled, thereby accelerating the reaction between the chemical liquid 123 and the residue 25 to separate the residue 25 from its attached surface.

As shown in FIG. 1 and FIG. 3, after the chip-stacked structure 2 is placed, the two-fluid nozzle 140 is moved over the platform 110 by the precise driving device 170, to move the two-fluid nozzle 140 to reach a position in alignment with the interval 24 between two adjacent chips 21, and to move to reach a position in alignment with a first side 26 of the gap 23.

As shown in FIG. 1 and FIG. 2, the humidity of the gas 133 in the gas supply device 130 is increased by the humidifier 135, and the gas 133 in the gas supply device 130 is heated to a temperature close to the chemical liquid 123 by the heater 134. Next, the gas supply device 130 and the liquid supply device 120 transfer the gas 133 and the chemical liquid 123 to the two-fluid nozzle 140, respectively. The gas 133 and the chemical liquid 123 are mixed in the two-fluid nozzle 140 to form a gas-liquid mixture 150.

Next, as shown in FIG. 1, the gas-liquid mixture 150 is applied to the substrate 20 of the chip-stacked structure 2 by the two-fluid nozzle 140, so that the gas-liquid mixture 150 flows into the gap 23 along the first side 26 of the gap 23. Chemical cleaning reaction with the chemical liquid 123 of the gas-liquid mixture 150 and the residue 25 in gap 23 causes the residue 25 to separate from its attached surface. An impact force exerted by the gas 133 of the gas-liquid mixture 150 causes the residue 25 to be carried out of the second side 27 of gap 23. It should be noted that while the two-fluid nozzle 140 is spraying the gas-liquid mixture 150, the precise driving device 170 controls the two-fluid nozzle 140 to move along the horizontal direction. Preferably, the two-fluid nozzle 140 is moved in parallel along the interval 24 between two adjacent chips 21. However, in another embodiment, in order to simplify the control program, the precise driving device 170 can be set to move the two-fluid nozzle 140 from the interval 24 between two adjacent chips 21 to the other interval 24 between the other two adjacent chips 21 when moving in the X direction. After the two-fluid nozzle 140 sprays a full surface of chip-stacked structure 2 along the X direction, the platform 110 is rotated 90 degrees. When the precise driving device 170 moves the two-fluid nozzle 140 in the Y direction, the two-fluid nozzle 140 corresponds to the interval 24 between two adjacent chips 21, and moves in parallel along the direction in which the interval 24 extends. At this time, the spraying operation of the gas-liquid mixture 150 is simultaneously performed, and the above-mentioned full spraying operation is performed again, so that the gap 23 of the chip-stacked structure 2 is cleaned.

In the present disclosure, the liquid supply device 120 may provide a cleaning liquid such as pure water, deionized water or the like in addition to the chemical liquid 123. Also, after the residue 25 in the gap 23 is removed by the gas-liquid mixture 150, the liquid supply device 120 can be switched to provide the cleaning liquid to the two-fluid nozzle 140, so that the two-fluid nozzle 140 sprays the cleaning liquid to the chip-stacked structure 2 to remove the gas-liquid mixture 150 on the chip-stacked structure 2.

On the other hand, as shown in FIG. 1, when the two-fluid nozzle 140 sprays the gas-liquid mixture 150 or the cleaning liquid on the chip-stacked structure 2, the liquid and gas extracted through the extraction port 101 of the chamber 100 can be gas-liquid separated by the gas-liquid separation device 160. Preferably, the gas-liquid separation device 160 is provided with a filter that filters the extracted solid residue 25, and then separates the liquid from the gas. Finally, the liquid is introduced into a liquid recovery tank 161, and the gas is discharged. Therefore, the liquid recovered after the gas-liquid separation can be reused after being appropriately treated. In addition, a flow meter can be added to the liquid recovery tank 161 to record a pumping flow value.

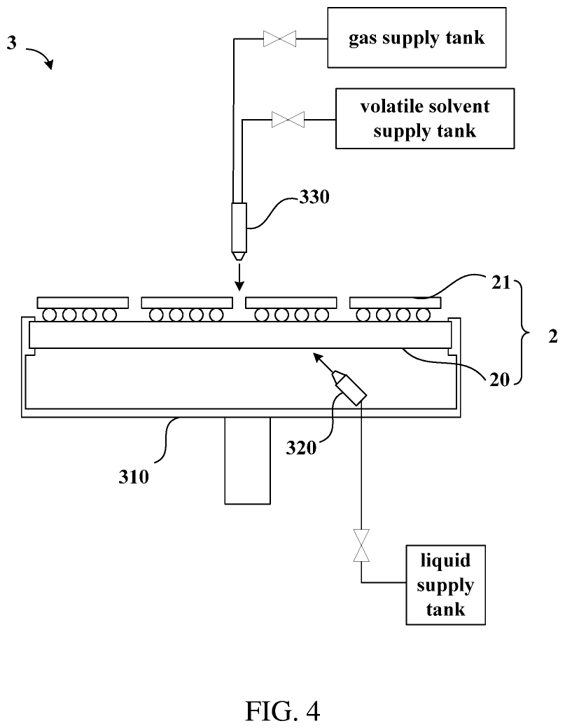

After removing the residue 25 in the gap 23 of the chip-stacked structure 2, the chip-stacked structure 2 is moved into a drying apparatus to perform final cleaning and drying steps on the chip-stacked structure 2. Referring to FIG. 4, which shows a schematic diagram of a drying apparatus 3 used in a cleaning method of the present disclosure. The drying apparatus 3 includes a rotatable clamping table 310, a first nozzle 320, and a two-fluid nozzle 330. The first nozzle 320 is connected to a liquid supply tank, and the two-fluid nozzle 330 is connected to a volatile solvent supply tank and a gas supply tank. After the chip-stacked structure 2 is moved to the drying apparatus, the first nozzle 320 sprays a cleaning liquid on a back side of the substrate 20 of the chip-stacked structure 2 to remove the residual gas-liquid mixture 150 on the back side of the substrate 20, where the cleaning liquid may be pure water, deionized water, etc.

After front and back sides of the chip-stacked structure 2 are cleaned, the volatile solvent and the drying gas are simultaneously supplied to the chip-stacked structure 2 through the two-fluid nozzle 330 to remove moisture on the surface of the chip-stacked structure 2, where the volatile solvent can be isopropyl alcohol (IPA), and the drying gas can be nitrogen. Alternatively, after the front and back sides of the chip-stacked structure 2 are cleaned, the chip-stacked structure 2 may be placed in an oven to remove moisture on the surface of the chip-stacked structure 2, and is not limited thereto.

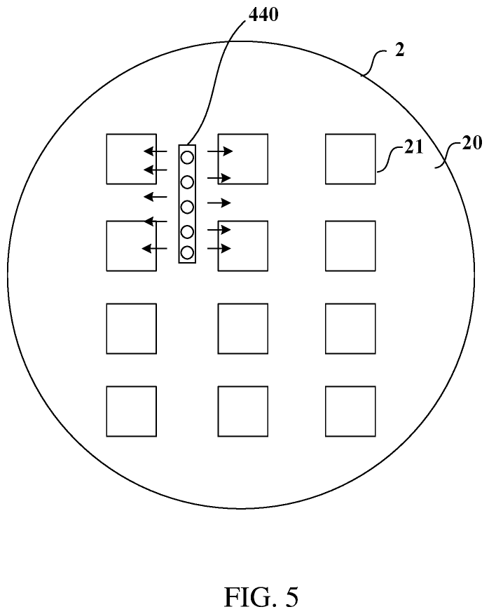

Referring to FIG. 5, which is an enlarged view showing a part of a cleaning apparatus according to a second preferred embodiment of the present disclosure. The cleaning apparatus of the second preferred embodiment is substantially the same as the cleaning apparatus 1 of the first preferred embodiment. The difference is that the cleaning apparatus of the second preferred embodiment uses a plurality of two-fluid nozzles 240, so that a plurality of gaps G between the chips 21 and the substrate 20 of the chip-stacked structure 2 can be cleaned at one time. Specifically, the plurality of two-fluid nozzles 440 are aligned in a row, and the plurality of two-fluid nozzles 440 can be moved to reach a position in alignment with a plurality of gaps G between two adjacent rows of chips 21. This design can effectively shorten a cleaning time of the chip-stacked structure 2 to improve cleaning performance.

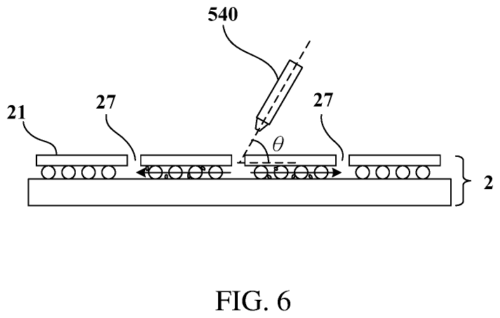

Referring to FIG. 6, which is an enlarged view showing a part of a cleaning apparatus according to a third preferred embodiment of the present disclosure. The cleaning apparatus of the third preferred embodiment is substantially the same as the cleaning apparatus 1 of the first preferred embodiment. The difference is that, in the cleaning apparatus of the third preferred embodiment, a front end of a two-fluid nozzle 540 is formed at an angle θ with respect to a surface of the chip-stacked structure 2 to be cleaned. Preferably, the angle θ is between 30 and 60 degrees. Also, with the precise driving device to control the two-fluid nozzle to move in a single direction for spraying, the resume R can be moved in the same direction. For example, when the two-fluid nozzle 540 is tilted in an upper right direction toward a lower left direction, and the precede driving device controls the two-fluid nozzle to move from the right to the left direction and the spraying operation is performed, and the resume R will be moved to the left. This design prevents the rescue R from being flushed back into the cleaned gap 23.

In summary, the present disclosure uses a two-fluid nozzle to apply a gas-liquid mixture to a chip-stacked structure in a cleaning apparatus, and cleans a residue on the chip-stacked structure by the gas-liquid mixture. Upon cleaning, a chemical liquid of the gas-liquid mixture separates the residue in the gap from its attached surface, and an impact force exerted by a gas of the gas-liquid mixture causes the residue to be carried out of the gap through a second side of the gap. The present disclosure adopts the two-fluid nozzle to apply the gas-liquid mixture to the chip-stacked structure, and a high pressure cleaning (HPC) nozzle can also be used to apply high pressure fluid to the chip-stacked structure, and the residue in the gap of the chip-stacked structure can be removed by the high pressure fluid. During cleaning, the high pressure liquid separates the residue in the gap from its attached surface, and an impact force exerted by the high pressure liquid causes the residue to be carried out of the gap through the second side of the gap. By this design, the present disclosure can achieve a non-contact cleaning of the chip-stacked structure, thereby avoiding the problem of chip damage caused by applying a downward pressure on the chip-stacked structure.

The above descriptions are merely preferable embodiments of the present disclosure, and are not intended to limit the scope of the present disclosure. Any modification or replacement made by those skilled in the art without departing from the spirit and principle of the present disclosure should fall within the protection scope of the present disclosure. Therefore, the protection scope of the present disclosure is subject to the appended claims.

What is claimed is:

1. A cleaning apparatus for removing residue from a chip-stacked structure, the chip-stacked structure comprising a substrate and a plurality of chips, a gap being defined between the chips and the substrate, and the residue being located in the gap, the cleaning apparatus comprising:
a platform configured to place the chip-stacked structure thereon;
a liquid supply device configured to provide a chemical liquid;
a gas supply device configured to provide a gas; and
a two-fluid nozzle movable relative to the platform to reach a position in alignment with an interval between two adjacent chips;
wherein the two-fluid nozzle is connected to the liquid supply device and the gas supply device and configured to apply a gas-liquid mixture comprising the chemical liquid and the gas to the substrate of the chip-stacked structure, such that the gas-liquid mixture flows into the gap along a first side of the gap; and
wherein the residue in the gap is separated from its attached surface by the chemical liquid of the gas-liquid mixture, and an impact force exerted by the gas of the gas-liquid mixture causes the residue to be carried out of the gap through a second side of the gap.

2. The cleaning apparatus as claimed in claim 1, further comprising a precise driving device configured to control the two-fluid nozzle to move along a vertical direction and a horizontal direction with respect to the platform.

3. The cleaning apparatus as claimed in claim 2, wherein the precise driving device comprises a vertical lifting mechanism configured to control the two-fluid nozzle to move along the vertical direction with respect to the platform, and the vertical lifting mechanism comprises a stepper motor.

4. The cleaning apparatus as claimed in claim 2, wherein the precise driving device comprises a horizontal moving mechanism configured to control the two-fluid nozzle to move along the horizontal direction with respect to the platform, and the horizontal moving mechanism comprises an X-Y table.

5. The cleaning apparatus as claimed in claim 1, further comprising a chamber, wherein the platform and the two-fluid nozzle are disposed in the chamber, and an extraction opening is provided at a bottom of the chamber.

6. The cleaning apparatus as claimed in claim 5, further comprising a gas-liquid separation device, wherein the gas-liquid separation device is connected to the extraction opening of the chamber for gas-liquid separation of the gas-liquid mixture which is extracted through the extraction opening.

7. The cleaning apparatus as claimed in claim 1, wherein the gas supply device comprises a heater configured to heat the gas in the gas supply device to a temperature substantially the same as a temperature of the chemical liquid.

8. The cleaning apparatus as claimed in claim 1, wherein the gas supply device comprises a humidifier configured to increase humidity of the gas in the gas supply device.

9. The cleaning apparatus as claimed in claim 1, wherein the platform comprises another heater configured to heat the chip-stacked structure on the platform to maintain it at a processing temperature.

10. The cleaning apparatus as claimed in claim 1, wherein the cleaning apparatus comprises a plurality of two-fluid nozzles arranged in a row in a side-by-side manner, and the plurality of two-fluid nozzles are movable relative to the platform to reach a position in alignment with an interval between two adjacent rows of chips.

11. The cleaning apparatus as claimed in claim 1, wherein a front end of the two-fluid nozzle of the cleaning apparatus is formed at an angle with respect to a surface of the chip-stacked structure to be cleaned.

12. The cleaning apparatus as claimed in claim 1, wherein the two-fluid nozzle comprises a high-pressure cleaning nozzle.

13. A cleaning method, performed by a cleaning apparatus which comprises a platform, a liquid supply device, a gas supply device, a two-fluid nozzle, and a precise driving device, and the cleaning method used for removing residue from a chip-stacked structure, and the chip-stacked structure comprising a substrate and a plurality of chips, a gap being defined between the chips and the substrate, and the residue being located in the gap, the cleaning method comprising:
placing the chip-stacked structure on the platform;
controlling the precise driving device to move the two-fluid nozzle to reach a position in alignment with an interval between two adjacent chips;
providing a chemical liquid to the two-fluid nozzle by the liquid supply device, and providing a gas to the two-fluid nozzle by the gas supply device;
applying a gas-liquid mixture comprising the chemical liquid and the gas to the substrate of the chip-stacked structure, such that the gas-liquid mixture flows into the gap along a first side of the gap, wherein the residue in the gap is separated from its attached surface by the chemical liquid of the gas-liquid mixture, and an impact force exerted by the gas of the gas-liquid mixture causes the residue to be carried out of the gap through a second side of the gap.

14. The cleaning method as claimed in claim 13, after the chip-stacked structure is placed on the platform, further comprising: controlling a horizontal movement of the two-fluid nozzle over the platform by a horizontal moving mechanism of the precise driving device, and controlling the two-fluid nozzle to move along a vertical direction with respect to the platform by a vertical lifting mechanism of the precise driving device to align the two-fluid nozzle with the first side of the gap.

15. The cleaning method as claimed in claim 14, wherein the horizontal moving mechanism comprises an X-Y table.

16. The cleaning method as claimed in claim 13, wherein the cleaning apparatus further comprises a chamber and a gas-liquid separation device, wherein an extraction opening is provided at a bottom of the chamber, and the gas-liquid separation device is connected with the extraction opening of the chamber, and the cleaning method also comprises: performing gas-liquid separation of the gas-liquid mixture which is extracted through the extraction opening by the gas-liquid separation device.

17. The cleaning method as claimed in claim 13, wherein the gas supply device of the cleaning apparatus further comprises a heater, and before the gas supply device provides a gas to the two-fluid nozzle, the cleaning method further comprises: heating the gas in the gas supply device to a temperature substantially the same as a temperature of the chemical liquid by the heater.

18. The cleaning method as claimed in claim 13, wherein the gas supply device of the cleaning apparatus further comprises a humidifier, and before the gas supply device provides a gas to the two-fluid nozzle, the cleaning method further comprises: increasing humidity of the gas in the gas supply device by the humidifier.

19. The cleaning method as claimed in claim 13, wherein the platform of the cleaning apparatus further comprises another heater, and the cleaning method further comprises: heating the chip-stacked structure on the platform by the heater to maintain it at a processing temperature.

20. The cleaning method as claimed in claim 13, after the residue in the gap is removed by the gas-liquid mixture, further comprising:
providing a cleaning liquid to the two-fluid nozzle by the liquid supply device; and
spraying the cleaning liquid on the chip-stacked structure by the two-fluid nozzle to remove the gas-liquid mixture on the chip-stacked structure.
